(19) United States
(12) Patent Application Publication
(10) Pub. No.: US 2026/0057947 A1
(43) Pub. Date: Feb. 26, 2026

(54) STORAGE DEVICE INCLUDING DUMMY WORD LINES AND OPERATING METHOD THEREOF

(71) Applicant: Samsung Electronics Co., Ltd., Suwon-si (KR)

(72) Inventors: Yejin Park, Suwon-si (KR); Shinkeun Kim, Suwon-si (KR); Na-Young Choi, Suwon-si (KR); Ji-Sang Lee, Suwon-si (KR)

(21) Appl. No.: 19/265,581

(22) Filed: Jul. 10, 2025

(30) Foreign Application Priority Data
Aug. 23, 2024 (KR) 10-2024-0113496

(51) Int. Cl. G11C 16/30; G11C 16/08

(52) U.S. Cl. CPC G11C 16/30; G11C 16/08

(57) ABSTRACT

Disclosed is a storage device which includes a non-volatile memory device and a storage controller. Based on a program request for a target memory cell of a first stack, the storage controller provides a first program command to the non-volatile memory device, in response to determining that the number of programmed memory cells of a second stack is one or more. The second stack includes a first dummy word line and a second dummy word line disposed adjacent to an upper end and a lower end of the second stack, respectively. Based on the first program command, control logic applies a first voltage greater than a pass voltage to a dummy word line closer to the first stack and applies a second voltage smaller than the pass voltage to a dummy word line more.

### CROSS-REFERENCE TO RELATED APPLICATION

This application claims priority under 35 U.S.C. § 119 to Korean Patent Application No. 10-2024-0113496 filed on Aug. 23, 2024, in the Korean Intellectual Property Office, the disclosures of which are incorporated by reference herein in their entireties.

### BACKGROUND

A memory device stores data in response to a write request and outputs data stored therein in response to a read request. For example, the memory device is classified as a volatile memory device, which loses data stored therein when a power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

As highly integrated semiconductor chips and a high-capacity semiconductor chips are developed, nowadays, a non-volatile memory device, in which memory cells are stacked in a three-dimensional structure, such as a vertical NAND flash memory device is being actively developed.

### SUMMARY

Three-dimensional memory structures may exhibit increased disturbance which unselected memory cells experience in a program operation. Some aspects of the present disclosure provide storage devices that reduce or otherwise compensate for this disturbance increase.

Some aspects of the present disclosure provide storage devices including dummy word lines and operating methods thereof.

According to some implementations of the present disclosure, a storage device includes a non-volatile memory device that includes at least one memory block divided into a plurality of stacks disposed in a vertical direction, and a storage controller. Based on a program request for a target memory cell of a first stack among the plurality of stacks, the storage controller provides a first program command to the non-volatile memory device, in response to determining that the number of programmed memory cells of a second stack among the plurality of stacks is one or more. The second stack includes a first dummy word line and a second dummy word line disposed adjacent to an upper end and a lower end of the second stack, respectively. Based on the first program command, control logic of the non-volatile memory device applies a first voltage greater than a pass voltage to a dummy word line closer to the first stack from among the first and second dummy word lines and applies a second voltage smaller than the pass voltage to a dummy word line more distant from the first stack from among the first and second dummy word lines.

According to some implementations of the present disclosure, a storage device includes a non-volatile memory device that includes at least one memory block divided into a plurality of stacks disposed in a vertical direction, and a storage controller. Based on a program request for a target memory cell of a first stack among the plurality of stacks, the storage controller provides a first program command to the non-volatile memory device, in response to determining that the combined number of programmed memory cells of a second stack and a third stack among the plurality of stacks is one or more. The second stack includes a first dummy word line and a second dummy word line disposed adjacent to an upper end and a lower end of the second stack, respectively. The third stack includes a third dummy word line and a fourth dummy word line disposed adjacent to an upper end and a lower end of the third stack, respectively. Based on the first program command, control logic of the non-volatile memory device applies a first voltage greater than a pass voltage to a dummy word line the closest to the first stack from among the first to fourth dummy word lines and applies a second voltage smaller than the pass voltage to a dummy word line the most distant from the first stack from among the first to fourth dummy word lines.

According to some implementations of the present disclosure, an operating method of a storage device which includes a non-volatile memory device including at least one memory block divided into a plurality of stacks disposed in a vertical direction and a storage controller includes determining, by the storage controller, whether the number of programmed memory cells of a second stack among the plurality of stacks is one or more, based on a program request for a target memory cell of a first stack among the plurality of stacks, the second stack including a first dummy word line and a second dummy word line disposed adjacent to an upper end and a lower end of the second stack, respectively, providing, by the storage controller, a first program command to the non-volatile memory device, in response to determining that the number of the programmed memory cells is one or more, applying, by control logic of the non-volatile memory device, a first voltage higher than a pass voltage to a dummy word line closer to the first stack from among the first and second dummy word lines, based on the first program command, and applying, by the control logic of the non-volatile memory device, a second voltage lower than the pass voltage to a dummy word line more distant from the first stack from among the first and second dummy word lines, based on the first program command.

### BRIEF DESCRIPTION OF THE FIGURES

The above and other objects and features of the present disclosure will become apparent by describing in detail examples thereof with reference to the accompanying drawings.

FIG. 1 is a block diagram of an example of a storage system.

FIG. 2 is a block diagram illustrating an example of a storage controller.

FIG. 3 is a block diagram illustrating an example of a non-volatile memory device.

FIG. 4 is a diagram illustrating a memory block of a memory cell array of a non-volatile memory device.

FIG. 5 is a circuit diagram illustrating an example of a structure of a first memory block of a non-volatile memory device.

FIG. 6 is a diagram illustrating examples of threshold voltage distributions of single level cells.

FIG. 7 is a diagram illustrating how a channel voltage of memory cells changes depending on whether a stack is programmed.

FIG. 8 is a block diagram illustrating an example of a storage device.

FIG. 9 is a cross-sectional view of an example of a memory block divided into two stacks.

FIG. 10 is a timing diagram illustrating examples of voltages applied to a memory block according to some implementations of the present disclosure.

FIG. 11 is a cross-sectional view of an example of a memory block divided into two stacks.

FIG. 12 is a timing diagram illustrating examples of voltages applied to a memory block according to some implementations of the present disclosure.

FIG. 13 is a cross-sectional view of an example of a memory block divided into three stacks.

FIG. 14 is a cross-sectional view of an example of a memory block divided into three stacks.

FIG. 15 is a flowchart illustrating an example of an operating method of a storage device.

### DETAILED DESCRIPTION

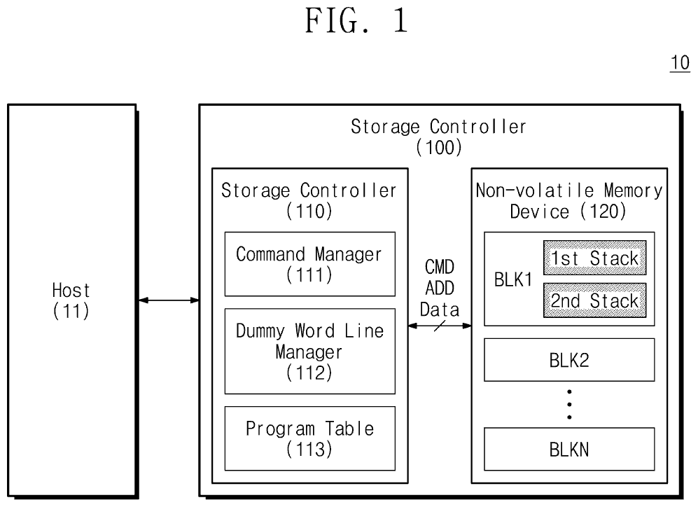

FIG. 1 is a block diagram of a storage system. Referring to FIG. 1, a storage system 10 may include a host 11 and a storage device 100. In some implementations, the storage system 10 refers to a computing system, which is configured to process a variety of information, such as a personal computer (PC), a notebook, a laptop, a server, a workstation, a tablet PC, a smartphone, a digital camera, or a black box.

The host 11 may control operations of the storage system 10. For example, the host 11 may store data in the storage device 100 or may read data stored in the storage device 100.

The storage device 100 may include a storage controller 110 and a non-volatile memory device 120. The non-volatile memory device 120 may store data. The storage controller 110 may store data in the non-volatile memory device 120 or may read data stored in the non-volatile memory device 120. The non-volatile memory device 120 may operate under control of the storage controller 110. For example, based on a command CMD indicating an operation and an address ADD indicating a location of data, the storage controller 110 may store data in the non-volatile memory device 120 or may read data stored in the non-volatile memory device 120.

The non-volatile memory device 120 may include a plurality of memory blocks BLK1 to BLKN. Each of the plurality of memory blocks BLK1 to BLKN may be implemented in a multi-stack structure including a plurality of stacks. For example, the first memory block BLK1 may include a first stack and a second stack. Each of the plurality of memory blocks BLK1 to BLKN may include a plurality of word lines. Each of the plurality of word lines may include a plurality of memory cells. The plurality of memory cells may store data.

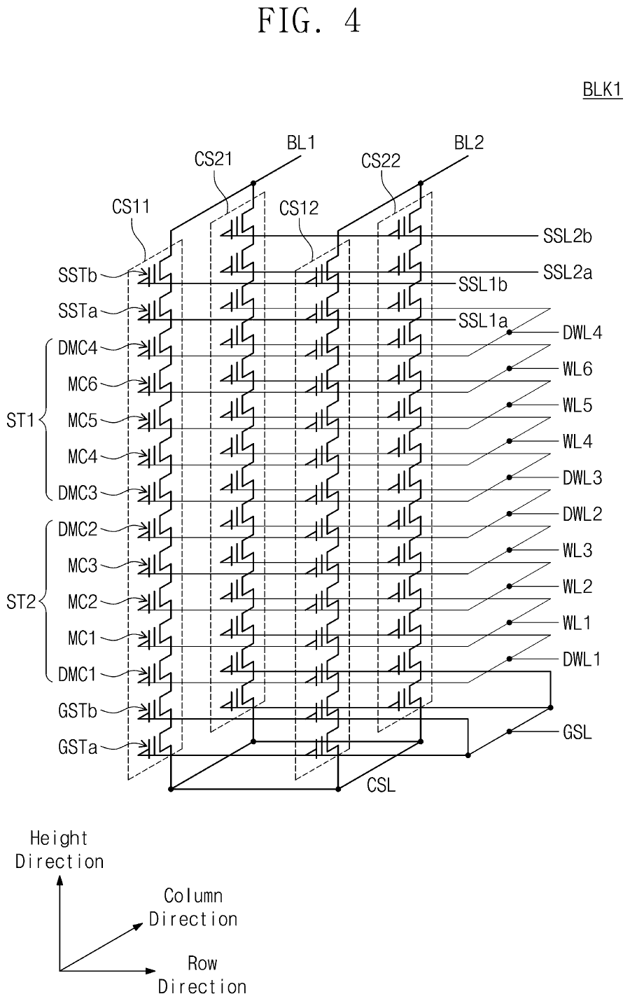

In some implementations, each of the plurality of memory blocks BLK1 to BLKN includes at least one dummy word lines adjacent to the boundary between the stacks. In some implementations, each of the plurality of memory blocks BLK1 to BLKN includes at least one dummy word lines adjacent to an upper end and a lower end of each of a plurality of stacks. The dummy word line may include a plurality of dummy memory cells. The dummy memory cell may indicate a memory cell which does not store data. The plurality of memory blocks BLK1 to BLKN will be described in detail with reference to FIG. 4.

In some implementations, the non-volatile memory device 120 is a NAND flash memory device, but the present disclosure is not limited thereto. For example, the non-volatile memory device 120 may be one of various storage devices, which retain data stored therein even when a power is turned off, such as a phase-change random access memory (PRAM), a magnetic random access memory (MRAM), a resistive random access memory (RRAM), and a ferroelectric random access memory (FRAM).

The storage controller 110 may include a command manager 111, a dummy word line manager 112, and a program table 113.

The command manager 111 may manage various commands indicating operations to be performed in the non-volatile memory device 120. For example, the command manager 111 may provide the non-volatile memory device 120 with various commands such as a read command, a program command, and an erase command.

For example, the command manager 111 may manage the program command which manages the dummy word lines individually. For example, when the non-volatile memory device 120 performs the program operation, the command manager 111 may manage a command which determines a voltage to be applied to the dummy word lines. The command manager 111 may generate the program command depending on a request of the dummy word line manager 112 and may provide the generated program command to the non-volatile memory device 120.

The dummy word line manager 112 may request the command manager 111 to generate the program command, based on the program request received from the host 11. For example, the program request may indicate the program operation for a target memory cell of the non-volatile memory device 120. The target memory cell may indicate a memory cell in which data included in the program request of the host 11 are programmed.

For example, based on the program request for a target memory cell of the first stack, the dummy word line manager 112 may determine whether the number of programmed memory cells among memory cells of the second stack is one or more.

In some implementations, based on determining that the number of programmed memory cells among memory cells of the second stack is one or more, the dummy word line manager 112 requests the command manager 111 to generate an individual control program command. The individual control program command may indicate an operation of controlling the dummy word lines of the second stack individually in the program operation for the target memory cell of the first stack.

For example, based on the individual control program command, the non-volatile memory device 120 may apply a voltage greater than a pass voltage to a dummy word line close to the first stack from among the dummy word lines of the second stack and may apply a voltage smaller than the pass voltage to a dummy word line distant from the first stack. The pass voltage may indicate a voltage which is applied to an unselected word line.

In some implementations, based on determining that a programmed memory cell is absent from the memory cells of the second stack, the dummy word line manager 112 may request the command manager 111 to generate an identical control program command. The identical control program command may indicate an operation of controlling the dummy word lines of the second stack to be identical to an unselected word line, in the program operation for the target memory cell of the first stack.

For example, based on the identical control program command, the non-volatile memory device 120 may apply the pass voltage to each of the dummy word lines of the second stack.

In some implementations, by referring to the program table 113, the dummy word line manager 112 may determine whether the number of programmed memory cells among the memory cells of the second stack is one or more.

The program table 113 may include information about a plurality of stacks and program status information corresponding to each of the plurality of stacks. The program status information may indicate whether each stack includes one or more programmed memory cells.

For example, the dummy word line manager 112 may update the program table 113 based on a request received from the host 11. For example, the dummy word line manager 112 may update program status information corresponding to the second stack in the program table 113, based on a request indicating the program operation for memory cells of the second stack received from the host 11.

As another example, the dummy word line manager 112 may update the program table 113 based on a response received from the non-volatile memory device 120. For example, the dummy word line manager 112 may update program status information corresponding to the second stack in the program table 113 based on a response indicating program completion for the memory cells of the second stack from the non-volatile memory device 120.

In a storage device including a plurality of stacks, the program operation may be performed in a top-to-bottom (T2B) order (or manner) or a bottom-to-top (B2T) order (or manner). The T2B manner indicates a manner of performing the program operation toward the bottom from a word line disposed to be higher based on the height direction in one stack. The B2T manner indicates a manner of performing the program operation toward the top from a word line disposed to be lower based on the height direction in one stack.

In the case of performing the program operation on a target memory cell of a first stack, when a memory cell of a second stack different from the first stack is already programmed, the disturbance which an unselected memory cell of the first stack experiences may become greater.

As described above, according to some implementations of the present disclosure, depending on whether the second stack not including the target memory cell is programmed, the dummy word lines of the second stack may be individually adjusted when the program operation on the target memory cell is performed. Accordingly, it may be possible to reinforce a self-boosting voltage in association with an unselected memory cell connected to the same word line as the target memory cell, and it may be possible to reduce the disturbance which the unselected memory cell experiences.

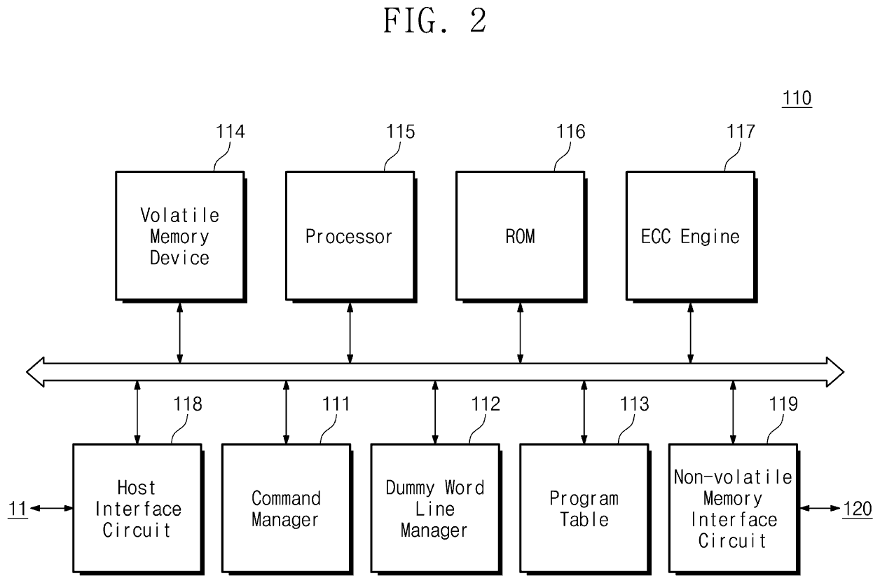

FIG. 2 is a block diagram illustrating an example of the storage controller 110 of FIG. 1 in detail. Referring to FIG. 2, the storage controller 110 may include the command manager 111, the dummy word line manager 112, the program table 113, a volatile memory device 114, a processor 115, a read only memory (ROM) 116, an error correction code (ECC) engine 117, a host interface circuit 118, and a non-volatile memory interface circuit 119.

The command manager 111 may manage commands indicating operations to be performed in the non-volatile memory device 120. The dummy word line manager 112 may manage a voltage to be applied to dummy word lines depending on stack-specific program status information of the non-volatile memory device 120. The program table 113 may include information about a plurality of stacks and program status information corresponding to each of the plurality of stacks.

In some implementations, the command manager 111, the dummy word line manager 112, and the program table 113 are implemented with a firmware module. For example, the processor 115 may implement the command manager 111, the dummy word line manager 112, and the program table 113 by loading instructions stored in the non-volatile memory device 120 to the volatile memory device 114 and executing the loaded instructions. However, the present disclosure is not limited thereto. For example, the command manager 111, the dummy word line manager 112, and the program table 113 may be implemented with separate hardware or may be implemented with a combination of hardware and software.

The volatile memory device 114 may be used as a main memory, a buffer memory, or a cache memory of the storage controller 110. The processor 115 may control operations of the storage controller 110. The ROM 116 may be used as a read only memory which stores information necessary for the operation of the storage controller 110.

The ECC engine 117 may detect and correct an error of data obtained from the non-volatile memory device 120. For example, the ECC engine 117 may have an error correction capability of a given level. The ECC engine 117 may manage data having an error level (e.g., the number of flipped bits) exceeding the error correction capability as an uncorrectable error.

The storage controller 110 may communicate with the host 11 through the host interface circuit 118. In some implementations, the host interface circuit 118 is implemented based on at least one of various interfaces such as a serial ATA (SATA) interface, a peripheral component interconnect express (PCIe) interface, a serial attached SCSI (SAS) interface, a non-volatile memory express (NVMe) interface, and a universal flash storage (UFS) interface.

The storage controller 110 may communicate with the non-volatile memory device 120 through the non-volatile memory interface circuit 119. In some implementations, the non-volatile memory interface circuit 119 is implemented based on the NAND interface.

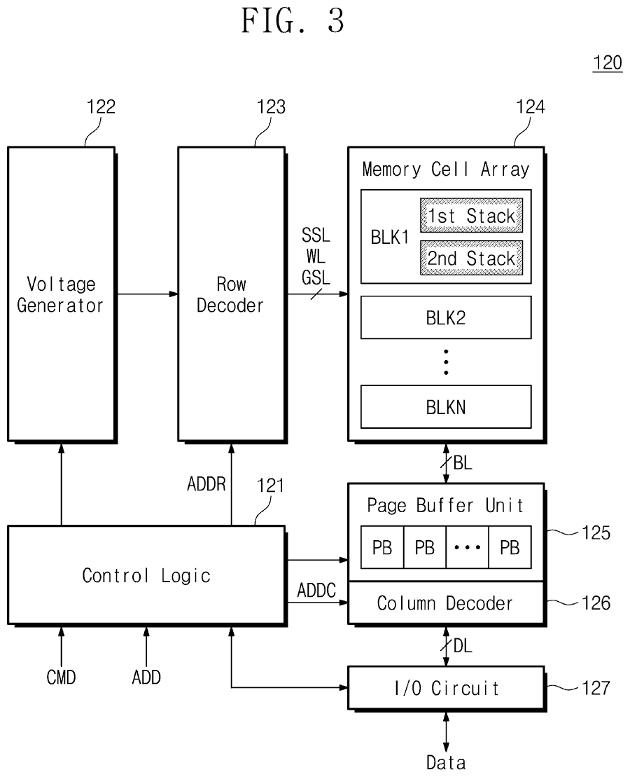

FIG. 3 is a block diagram illustrating an example of a non-volatile memory device, e.g., the non-volatile memory device 120 of FIG. 1 FIG. 4 is a diagram illustrating an example of a memory block of a memory cell array, e.g., the memory cell array of FIG. 3. Referring to FIGS. 1, 3, and 4, the non-volatile memory device 120 may communicate with the storage controller 110. For example, the non-volatile memory device 120 may receive the address ADD and the command CMD from the storage controller 110. The non-volatile memory device 120 may perform data communication with the storage controller 110.

The non-volatile memory device 120 may include control logic 121, a voltage generator 122, a row decoder 123, a memory cell array 124, a page buffer unit 125, a column decoder 126, and an input/output (I/O) circuit 127.

The control logic 121 may receive the command CMD and the address ADD from the storage controller 110. The command CMD may refer to a signal indicating an operation to be performed by the non-volatile memory device 120, such as a read operation, a program operation, or an erase operation. The address ADD may include a row address ADDR and a column address ADDC. The control logic 121 may control operations of the non-volatile memory device 120 based on the command CMD and the address ADD. The control logic 121 may generate the row address ADDR and the column address ADDC based on the address ADD.

Under control of the control logic 121, the voltage generator 122 may control voltages to be applied to the memory cell array 124 through the row decoder 123.

The row decoder 123 may receive the row address ADDR from the control logic 121. The row decoder 123 may be connected to the memory cell array 124 through string selection lines SSL, word lines WL, and ground selection lines GSL. The row decoder 123 may decode the row address ADDR and may control voltages to be applied to the string selection lines SSL, the word lines WL, and the ground selection lines GSL based on a decoding result and voltages received from the voltage generator 122.

The memory cell array 124 may include the plurality of memory blocks BLK1 to BLKN. Each of the plurality of memory blocks BLK1 to BLKN may be similar in structure to the first memory block BLK1 illustrated in FIG. 4. The first memory block BLK1 illustrated in FIG. 4 may correspond to a physical erase unit of the non-volatile memory device 120, but the present disclosure is not limited thereto. For example, the physical erase unit may be changed to a page unit, word unit, a sub-block unit, etc.

The first memory block BLK1 may include a plurality of cell strings CS11, CS12, CS21, and CS22. The plurality of cell strings CS11, CS12, CS21, and CS22 may be arranged in a row direction and a column direction to form rows and columns.

Each of the plurality of cell strings CS11, CS12, CS21, and CS22 includes a plurality of cell transistors. For example, each of the plurality of cell strings CS11, CS12, CS21, and CS22 may include string selection transistors SSTa and SSTb, a plurality of memory cells MC1 to MC6, ground selection transistors GSTa and GSTb, and dummy memory cells DMC1 to DMC4.

In some implementations, the first memory block BLK1 includes a plurality of stacks. For example, the first memory block BLK1 may include a first stack ST1 and a second stack ST2 stacked in the height direction (in other words, the vertical direction) being a direction perpendicular to a plane formed by the row direction and the column direction or a substrate. For example, the height direction can be perpendicular to a surface of the substrate. The first stack ST1 may be disposed above the second stack ST2 in the height direction.

The first stack ST1 may include the plurality of memory cells MC4 to MC6 and the plurality of dummy memory cells DMC3 and DMC4 between the string selection transistors SSTa and SSTb and the second stack ST2. The first stack ST1 may include the dummy memory cells DMC3 and DMC4 respectively adjacent to the upper end and the lower end of the first stack ST1.

The second stack ST2 may include the plurality of memory cells MC1 to MC3 and the plurality of dummy memory cells DMC1 and DMC2 between the first stack ST1 and the ground selection transistors GSTa and GSTb. The second stack ST2 may include the dummy memory cells DMC2 and DMC1 respectively adjacent to the upper end and the lower end of the second stack ST2.

In some implementations, each of the plurality of stacks ST1 and ST2 includes at least one dummy word lines adjacent to the boundary between the stacks.

An example in which the first memory block BLK1 includes two stacks is illustrated in FIG. 4, but the scope of the present disclosure is not limited thereto. For example, the first memory block BLK1 may include three or more stacks. Also, an example in which one dummy word line is adjacent to each of the upper end and the lower end of each stack is described, but the scope of the present disclosure is not limited thereto. For example, two or more dummy word lines may be adjacent to the upper end and/or the lower end of each stack. In this case, the dummy word lines disposed adjacent to the upper end of each stack may be controlled to be similar to each other, and the dummy word lines disposed adjacent to the lower end of each stack may be controlled to be similar to each other.

In some implementations, each of a plurality of cell transistors included in the cell strings CS11, CS12, CS21, and CS22 is a charge trap flash (CTF) memory cell.

The plurality of memory cells MC1 to MC6 and the plurality of dummy memory cells DMC1 to DMC4 are connected in series and are stacked in the height direction. The string selection transistors SSTa and SSTb are connected in series, and the serially-connected string selection transistors SSTa and SSTb are provided between the dummy memory cell DMC4 and a bit line BL1 or BL2. The ground selection transistors GSTa and GSTb are connected in series between the dummy memory cell DMC1 and a common source line CSL.

The ground selection transistors GSTa and GSTb may be connected to the same ground selection line GSL. However, the present disclosure is not limited thereto. For example, ground selection transistors, which belong to the same row, from among the ground selection transistors GSTa or GSTb placed at the same height may be connected to the same ground selection line, and ground selection transistors, which belong to another row, from among the ground selection transistors GSTa or GSTb may be connected to another ground selection line. In some implementations, ground selection transistors at same heights are connected to the same ground selection line. In some implementations, ground selection transistors belonging to at least two rows from among ground selection transistors at the same height are connected to the same ground selection line, and ground selection transistors belonging to at least two other rows from among the ground selection transistors at the same height are connected with another ground selection line. In some implementations, ground selection transistors at different heights are connected to the same ground selection line. A connection relationship between the ground selection transistors GSTa and GSTb and the ground selection line GSL may be variously changed and modified, e.g., according to one or more of the foregoing and/or other configurations.

Memory cells of the same height from the substrate or the ground selection transistors GSTa and GSTb may be connected in common to the same word line, and memory cells of different heights therefrom may be connected to different word lines. For example, the first to sixth memory cells MC1 to MC6 of the cell strings CS11, CS12, CS21, and CS22 may be connected to first to sixth word lines WL1 to WL6.

String selection transistors, which belong to the same row, from among the first string selection transistors SSTa of the same height are connected to the same string selection line, and string selection transistors, which belong to another row, from among the first string selection transistors SSTa are connected to another string selection line. For example, the first string selection transistors SSTa of the cell strings CS11 and CS12 in the first row are connected in common to a string selection line SSL1a, and the first string selection transistors SSTa of the cell strings CS21 and CS22 in the second row are connected in common to a string selection line SSL2a.

Likewise, string selection transistors, which belong to the same row, from among the second string selection transistors SSTb at the same height, are connected to the same string selection line, and string selection transistors, which belong to another row, from among the second string selection transistors SSTb, are connected to another string selection line. For example, the second selection transistors SSTb of the cell strings CS11 and CS12 in the first row are connected in common to a string selection line SSL1b, and the second string selection transistors SSTb of the cell strings CS21 and CS22 in the second row are connected in common to a string selection line SSL2b.

In some implementations, dummy memory cells of the same height are connected to the same dummy word line, and dummy memory cells of different heights are connected with different dummy word lines. For example, the first dummy memory cell DMC1 may be connected to the first dummy word line DWL1, the second dummy memory cell DMC2 may be connected to the second dummy word line DWL2, the third dummy memory cell DMC3 may be connected to the third dummy word line DWL3, and the fourth dummy memory cell DMC4 may be connected to the fourth dummy word line DWL4.

In some implementations, a first erase control transistor is provided between the ground selection transistors GSTa and GSTb and the common source line CSL. A second erase control transistor may be provided between the bit line BL1 or BL2 and the string selection transistors SSTa and SSTb. The first and second erase control transistors may be used to charge channels of the cell strings CS11, CS12, CS21, and CS22 with an erase voltage or to erase the first memory block BLK1, based on a gate induced drain leakage (GIDL) phenomenon. In some implementations, the first erase control transistors of the cell strings CS11, CS12, CS21, and CS22 may be connected in common to a first erase control line. The second erase control transistors of the cell strings CS11, CS12, CS21, and CS22 may be connected in common to a second erase control line. However, the present disclosure is not limited thereto. For example, the first and second erase control transistors of the cell strings CS11, CS12, CS21, and CS22 may be connected to different erase control lines through various manners described above.

The first memory block BLK1 illustrated in FIG. 3 is provided as an example. The number of cell strings may increase or decrease, and the number of rows of cell strings and the number of columns of cell strings may increase or decrease depending on the number of cell strings. Also, the number of cell transistors (i.e., GST, MC, DMC, and SST) of the first memory block BLK1 may increase or decrease, and the height of the first memory block BLK1 may increase or decrease depending on the number of cell transistors. In addition, the number of lines GSL, WL, DWL, and SSL connected to the cell transistors may increase or decrease depending on the number of cell transistors.

Referring to FIGS. 3 and 4 again, the control logic 121 may control voltages which are respectively applied to the plurality of dummy word lines DWL1 to DWL4 through the voltage generator 122. For example, from a first time point after a verification interval and before a program execution interval to a second time point in the program execution interval, the control logic 121 may determine a voltage to be applied to the plurality of dummy word lines DWL1 to DWL4 depending on the program command received from the storage controller 110 of FIG. 1.

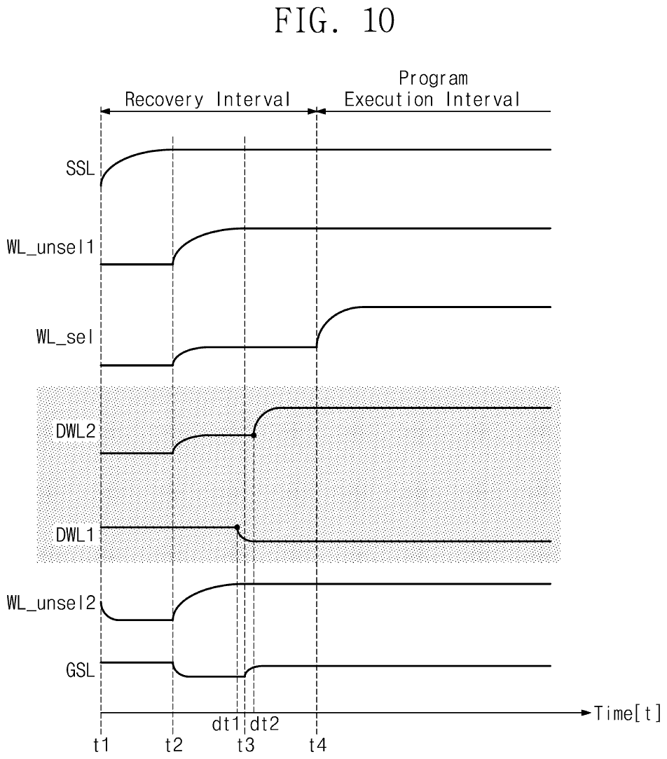

For example, when the control logic 121 receives the individual control program command indicating the program operation of a target memory cell in the first stack ST1 from the storage controller 110, the control logic 121 may apply a first voltage lower than the pass voltage to the first dummy word line DWL1 and may apply a second voltage higher than the pass voltage to the second dummy word line DWL2. In this case, the verification interval indicates the verification operation included in the program operation on the non-volatile memory device, and the program execution interval indicates the program execution operation included in the program operation on the non-volatile memory device. This will be described in detail with reference to FIG. 10.

As another example, when the control logic 121 receives the individual control program command indicating the program operation of a target memory cell in the second stack ST2 from the storage controller 110, the control logic 121 may apply the second voltage higher than the pass voltage to the third dummy word line DWL3 and may apply the first voltage lower than the pass voltage to the fourth dummy word line DWL4.

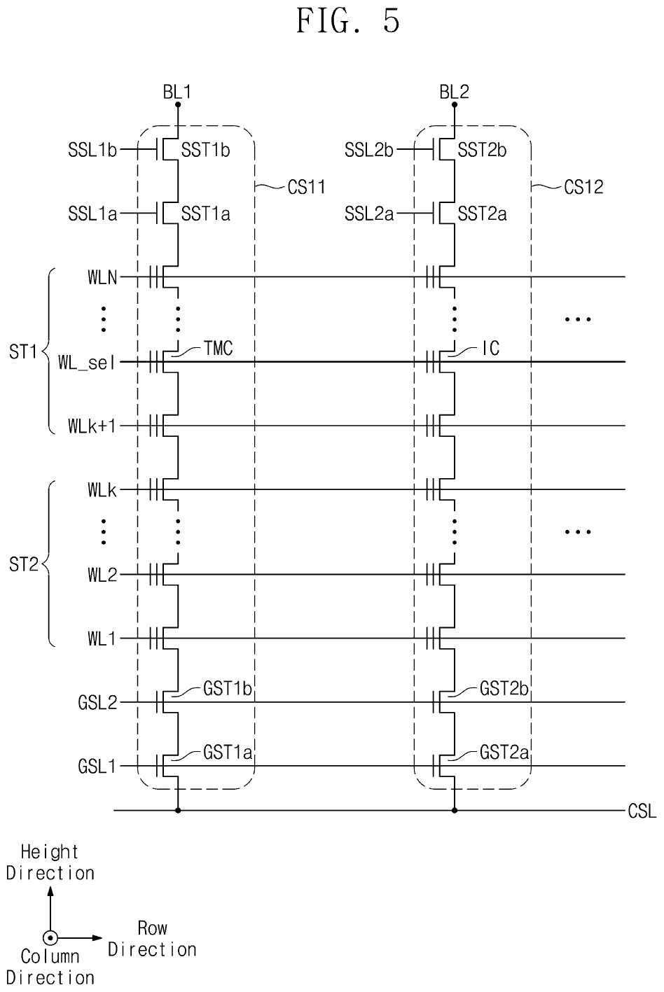

FIG. 5 is a circuit diagram partially illustrating a structure of a memory block. Components illustrated in FIG. 5 may respectively correspond to the components of FIG. 3, which are marked by the same reference signs. For convenience, the cell strings CS11 and CS12, which are connected to one common source line CSL and are respectively connected to different bit lines BL1 and BL2, from among cell strings of a memory block are illustrated in FIG. 5, and the memory block of FIG. 5 may have the third-dimensional structure described with reference to FIG. 4.

The memory block may include the first stack ST1 and the second stack ST2. The second stack ST2 may include first to k-th word lines WL1 to WLk. The first stack ST1 may include (k+1)-th to N-th word lines WLk+1 to WLN. The first stack ST1 may include a target memory cell TMC. The target memory cell TMC indicates a memory cell targeted for the program operation. The target memory cell TMC may be connected to one selected word line WL_sel among the (k+1)-th to N-th word lines WLk+1 to WLN. In some implementations, “N” is a natural number of 2 or more.

When the target memory cell TMC is programmed, a memory cell (e.g., an inhibit cell IC) which is connected to the same word line WL_sel as the target memory cell TMC and is connected to the other cell string CS12 should be program-inhibited. In some implementations, the self-sensing scheme may be used such that the inhibit cell IC is not programmed.

First, 0 V may be applied to the gates of the ground selection transistors GST1a, GST1b, GST2a, and GST2b, and thus, a ground path may be blocked. A ground voltage may be applied to the first bit line BL1, and a power supply voltage may be applied to the second bit line BL2. At the same time, the power supply voltage may be applied to the gates of the string selection transistors SST1a, SST1b, SST2a, and SST2b such that the sources of the string selection transistors SST1a, SST1b, SST2a, and SST2b are charged, and thus, the string selection transistors SST2a, and SST2b may be shut off. In the program execution interval, the program voltage is applied to the selected word line WL_sel, and the pass voltage is applied to the unselected word lines (e.g., the first to k-th word lines WL1 to WLk and (k+1)-th to N-th word lines WLk+1 to WLN); in this case, the channel of the transistor of the inhibit cell IC is boosted. Accordingly, a potential difference between the floating gate and the channel of the transistor of the inhibit cell IC is incapable of forming an electric field to such an extent that the F-N tunneling is generated. As a result, the inhibit cell IC may be program-inhibited, that is, may maintain a previous state. In some implementations, “N” is a natural number of 4 or more, and “k” is a natural number which is smaller than “N” and is 2 or more.

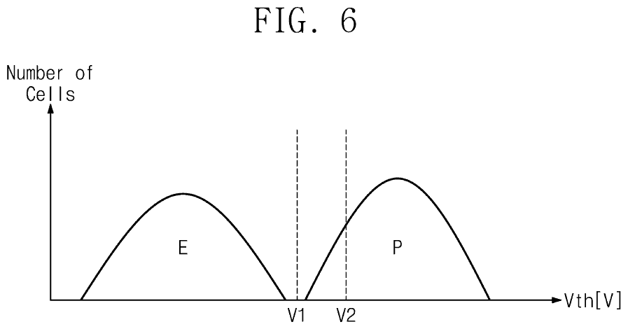

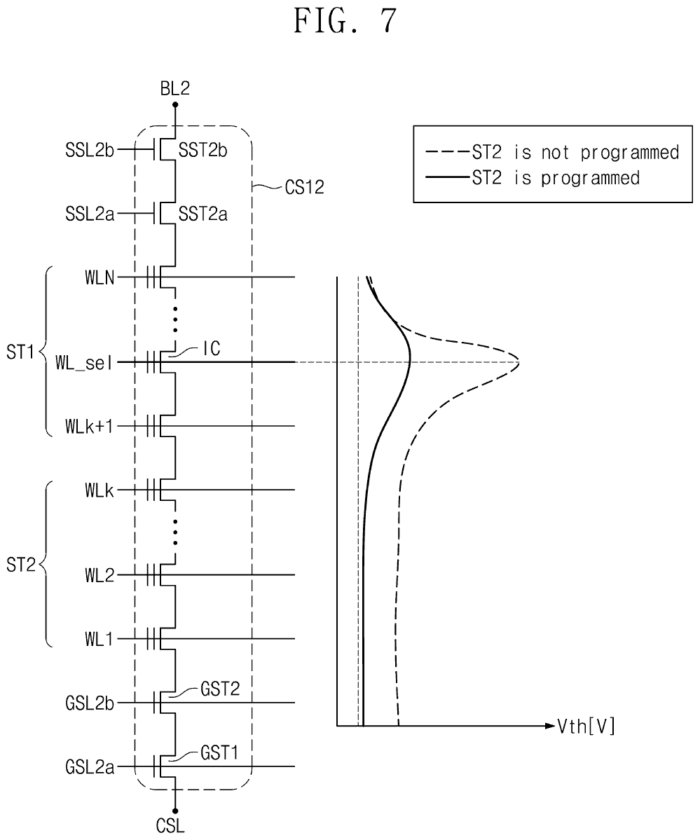

However, assuming that the non-volatile memory device performs the program operation in the T2B manner, when the target memory cell TMC is included in the first stack ST1 and the second stack ST2 includes one or more programmed memory cells, the channel boosting of the transistor of the inhibit cell IC may weaken. That is, the disturbance which the inhibit cell IC experiences may increase. This will be described in detail with reference to FIGS. 6 and 7.

FIG. 6 is a diagram illustrating threshold voltage distributions of single level cells (SLC) according to some implementations of the present disclosure. Threshold voltage distributions of single level cells each storing one bit are illustrated in FIG. 6. For convenience of description, the single level cell is intended to refer to a memory cell storing one bit, a memory cell storing two bits is referred to as a “multi-level cell (MLC)”, a memory cell storing three bits is referred to as a “triple level cell (TLC)”, and a memory cell storing four bits is referred to as a “quadruple level cell (QLC)”.

Referring to the graph of the single level cells SLC, the horizontal axis represents a threshold voltage (e.g., a level of a threshold voltage), and the vertical axis represents the number of memory cells. The single level cell SLC may have one of an erase state “E” and a program state “P” whose threshold voltage distributions sequentially increase.

The single level cell SLC may be turned on when a voltage higher than a threshold voltage is applied to the single level cell SLC. A voltage necessary to turn on the single level cell SLC of the program state “P” is higher than a voltage necessary to turn on the single level cell SLC of the erase state “E”.

For example, when a first voltage V1 is applied to the single level cell SLC, the single level cell SLC of the erase state “E” may be turned on, but the single level cell SLC of the program state “P” may not be turned on. When a second voltage V2 is applied to the single level cell SLC, the single level cell SLC of the erase state “E” may be turned on, and some single level cells SLC of the program state “P” may be turned on; however, the remaining single level cells SLC of the program state “P”, which have threshold voltages higher than the second voltage V2, may not be turned on.

FIG. 7 is a diagram describing how a channel voltage of memory cells changes depending on whether a stack is programmed. A circuit diagram of the cell string CS12 including the inhibit cell IC and a change graph of a channel voltage of memory cells are illustrated in FIG. 7. The cell string CS12 of FIG. 7 may correspond to the cell string CS21 of FIG. 5.

For convenience, the case where the program operation is performed in the T2B manner and a target memory cell is included in the first stack ST1 will be described.

In the change graph of the channel voltage, the horizontal axis represents a channel voltage Vth, and the vertical axis represents a cell location.

When all the memory cells of the second stack ST2 are in an erase state, that is, when the second stack ST2 is not programmed, during the program execution interval, the inhibit cell IC may have a channel voltage higher than the remaining memory cells by the self-boosting.

When the second stack ST2 includes one or more programmed memory cells, that is, when the second stack ST2 is programmed, a memory cell(s) of the program state “P” disposed between the common source line CSL and the inhibit cell IC may not be turned on. Accordingly, because charges for the channel voltage boosting of the inhibit cell IC are sufficiently induced in the channel, the channel voltage boosting of the inhibit cell IC may weaken. Also, the charge sharing that charges induced in the channel of the inhibit cell IC are leaked out to the channel of any other memory cells may be caused; in this case, the boosting may further weaken. That the boosting weakens means that the intensity of the electric field between the floating gate and the channel of the inhibit cell IC whose gate is provided with the program voltage increases. In other words, the inhibit cell IC may be programmed.

As described above, for convenience, the case where two stacks of the T2B manner are included is described, but the issue that the boosting of the channel voltage of the inhibit cell IC weakens may be similarly caused even in the case where the B2T manner is used or three or more stacks are included.

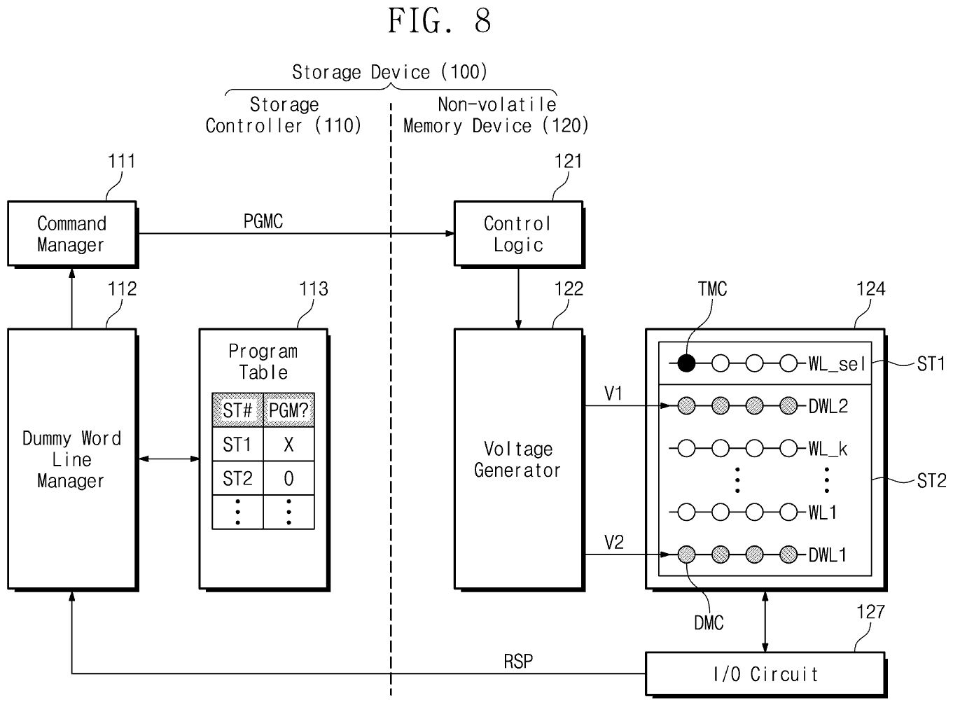

FIG. 8 is a block diagram illustrating a storage device according to some implementations of the present disclosure. For example, the storage device 100 including the storage controller 110 and the non-volatile memory device 120 is illustrated in FIG. 8.

The storage controller 110 may include the command manager 111, the dummy word line manager 112, and the program table 113. The non-volatile memory device 120 may include the control logic 121, the voltage generator 122, the memory cell array 124, and the I/O circuit 127. Components of FIG. 8 may correspond to the components of FIG. 1, which are marked by the same reference signs.

The memory cell array 124 may include the first stack ST1 and the second stack ST2. For convenience of description, an example in which the first stack ST1 is disposed above the second stack ST2 in the height direction and the second stack ST2 includes the first and second dummy word lines DWL1 and DWL2 is illustrated, but the scope of the present disclosure is not limited thereto. The second stack ST2 may be disposed above the first stack ST1, and the first stack ST1 may also include third and fourth dummy word lines respectively adjacent to the lower end and the upper end.

The dummy word line manager 112 may receive the program request indicating the program operation on the target memory cell TMC of the first stack ST1 from the host 11 of FIG. 1. The dummy word line manager 112 may determine whether to individually control dummy word lines, based on the program request.

The dummy word line manager 112 may determine whether the number of programmed memory cells among the memory cells of the second stack ST2 is one or more.

In some implementations, the dummy word line manager 112 determines whether the second stack ST2 is programmed, by referring to the program table 113.

For example, the program table 113 may include information about a plurality of stacks and program status information corresponding to each of the plurality of stacks. The program status information may indicate whether the corresponding stack is programmed. That the stack is programmed indicates that at least one memory cell in the stack is in a program state. In some implementations, the program status information indicates “O” (i.e., “programmed”) or “X” (i.e., “non-programmed”.

In some implementations, based on determining that the number of programmed memory cells in the second stack ST2 is one or more, the dummy word line manager 112 requests the command manager 111 to generate the individual control program command. Alternatively, based on determining that a programmed memory cell is absent from the second stack ST2, the dummy word line manager 112 requests the command manager 111 to generate the identical control program command.

The command manager 111 may provide a program command PGMC to the non-volatile memory device 120, based on the request of the dummy word line manager 112.

The control logic 121 may receive the program command PGMC from the command manager 111. Based on the program command PGMC, the control logic 121 may control voltages, which are used to program the target memory cell TMC and are applied to the dummy word lines DWL1 and DWL2 of the second stack ST2, through the voltage generator 122.

For example, when the program command PGMC is the individual control program command, from the first time point after the verification interval and before the program execution interval to the second time point in the program execution interval, the control logic 121 may apply the first voltage V1 higher than the pass voltage to a dummy word line closer to the first stack ST1 from among the first dummy word line DWL1 and the second dummy word line DWL2. Accordingly, the channel voltage boosting of the inhibit cell may be reinforced.

Also, when the program command PGMC is the individual control program command, from the first time point after the verification interval and before the program execution interval to the second time point from the program execution interval, the control logic 121 may apply the second voltage V2 lower than the pass voltage to a dummy word line distant from the first stack ST1 from among the first dummy word line DWL1 and the second dummy word line DWL2. Accordingly, because a current leakage decreases or is blocked at a dummy word line distant from the first stack ST1, the channel voltage boosting of the inhibit cell may be further reinforced. That is, the disturbance which the inhibit cell experiences may decrease. In this case, the leakage may indicate a leakage which is caused in the height direction at a selected string to which the inhibit cell is connected.

In some implementations, the first voltage V1 is a voltage higher than a first threshold voltage for turning on the dummy memory cell DMC connected to a dummy word line closer to the first stack ST1.

In some implementations, the second voltage V2 is a voltage lower than or equal to a second threshold voltage for turning off the dummy memory cell DMC connected to a dummy word line distant from the first stack ST1.

In some implementations, the second voltage V2 is a ground voltage.

The voltage generator 122 may apply voltages to a plurality of word lines and a plurality of dummy word lines of the memory cell array 124 under control of the control logic 121.

The I/O circuit 127 may provide the storage controller 110 with a response RSP indicating that the program operation on the memory cell array 124 is completed.

In some implementations, the dummy word line manager 112 receives the response RSP from the non-volatile memory device 120. The dummy word line manager 112 may update the program table 113, based on the response RSP. For example, when the response RSP indicates the program completion of the first stack ST1, the dummy word line manager 112 may change program status information corresponding to the first stack ST1 in the program table 113.

As another example, when the program command PGMC is the identical control program command, the control logic 121 may control the first dummy word line DWL1 and the second dummy word line DWL2 to be the same as (e.g., to receive the same voltage as) unselected word lines. In some implementations, during the program execution interval, the control logic 121 may apply the pass voltage to the first dummy word line DWL1 and the second dummy word line DWL2. In this case, the pass voltage may indicate a voltage which is applied to an unselected word line (e.g., a word line not including a target memory cell) during the program execution interval.

Accordingly, in the program operation of a non-volatile memory device including a plurality of stacks, it may be possible to determine situations where the channel voltage boosting of the inhibit cell weakens, and it may be possible to individually adjust voltages to be applied to dummy word lines placed at the boundary between stacks to reinforce the boosting of the channel voltage of the inhibit cell.

Below, various examples in which the channel voltage boosting of the inhibit cell is reinforced depending on the number of stacks and a program manner (e.g., the T2B or B2T manner) will be described.

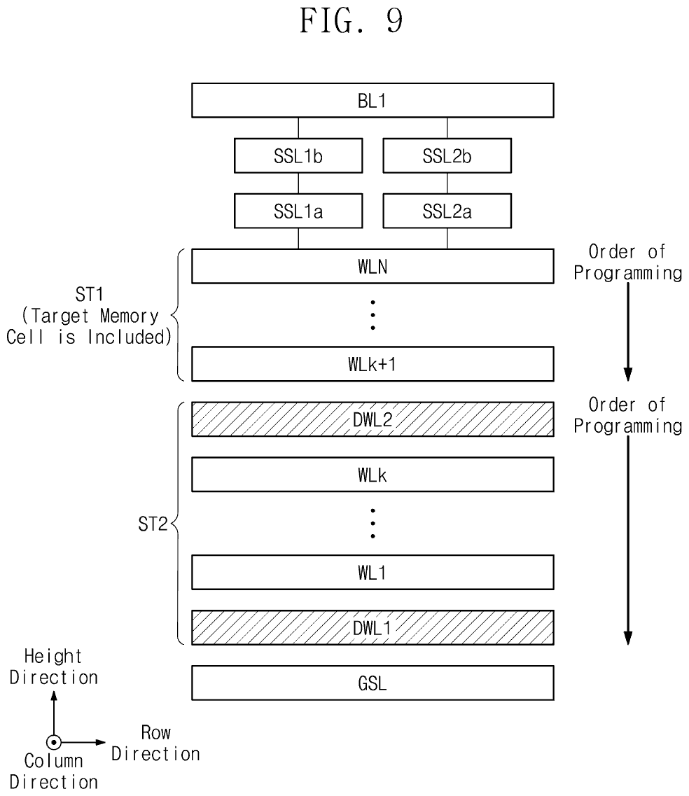

FIG. 9 is a cross-sectional view of a memory block divided into two stacks, according to some implementations of the present disclosure. Referring to FIG. 9, under the assumption that a memory block includes two stacks and is programmed in the T2B manner, as a first example, some operations of independently controlling dummy word lines of the lower stack when a target memory cell of the upper stack is programmed in a state where the lower stack is already programmed will be described.

The first stack ST1 and the second stack ST2 may be disposed between the first bit line BL1 and the ground selection line GSL from the top of the height direction. The plurality of string selection lines SSL1a, SSL1b, SSL2a, and SSL2b may be disposed between the first bit line BL1 and the first stack ST1.

The second stack ST2 may include the first to k-th word lines WL1 to WLk from the top of the height direction. The second stack ST2 may include the first dummy word line DWL1 between the ground selection line GSL and the first word line WL1. The second stack ST2 may include the second dummy word line DWL2 between the k-th word line WLk and the first stack ST1. That is, the first dummy word line DWL1 may be referred to as a “dummy word line” distant from the first stack ST1, and the second dummy word line DWL2 may be referred to as a “dummy word line” close to the first stack ST1. For convenience of description, the case where the number of dummy word lines distant from the first stack ST1 is “1” and the number of dummy word lines close to the first stack ST1 is “1” is illustrated, but the scope of the present disclosure is not limited thereto. For example, a plurality of dummy word lines distant from the first stack ST1 may be provided, and a plurality of dummy word lines close to the first stack ST1 may be provided; in this case, the control of the dummy word lines may be made to be similar to the above description.

The first stack ST1 and the second stack ST2 may be programmed in the T2B manner independently of each other. Accordingly, when a memory cell in the first stack ST1 is programmed, at least one memory cell in the second stack ST2 is already programmed.

FIG. 10 is a timing diagram describing voltages applied to a memory block of FIG. 9, according to some implementations of the present disclosure. Voltages which are applied to the memory block when the program operation on the target memory cell in the first stack ST1 of FIG. 9 is programmed in a state where the second stack ST2 is programmed will be described with reference to FIG. 10.

The ground selection line GSL and the dummy word lines DWL1 and DWL2 may respectively correspond to the ground selection line GSL and the dummy word lines DWL1 and DWL2 of FIG. 9. The string selection line SSL may correspond to one of the string selection lines SSL1a, SSL1b, SSL2a, and SSL2b of FIG. 9. The selected word line WL_sel indicates a word line connected to the target memory cell and may be one of the (k+1)-th to N-th word lines WLk+1 to WLN of FIG. 9. A first unselected word line WL_unsel1 may be one of the remaining word lines among the (k+1)-th to N-th word lines WLk+1 to WLN of FIG. 9 other than the selected word line WL_sel. A second unselected word line WL_unsel2 indicates one to the first to k-th word lines WL1 to WLk of FIG. 9.

The program operation may include a plurality of program loops, and each of the program loops may include a program execution operation, a program verification operation, and a recovery operation. The program execution operation may include an operation of applying the program voltage to a word line connected to a target memory cell. The program verification operation may include an operation of verifying a program state of the target memory cell. For example, when the target memory cell is a single level cell (SLC), whether the target memory cell is in a program state may be verified. As another example, when the target memory cell is a multi-level cell (MLC), whether the target memory cell is in one of first to third program states may be respectively verified. The recovery operation may include an operation of setting voltages of a plurality of lines (e.g., word lines, string selection lines, and ground selection lines) to preset recovery voltages.

Referring to FIG. 10 again, for convenience of description, the program verification interval is not illustrated, but the program verification operation may be performed after the program execution interval and before the recovery interval.

A first time point t1 indicates a point in time when the program verification operation ends and the recovery interval starts. The recovery operation may be performed from the first time point t1 to a fourth time point t4. The program execution interval may start from the fourth time point t4.

In detail, in the recovery interval, a time interval from t2 to t3 may be referred to as an “initial word line setting interval”. In the initial word line setting interval, a precharge voltage may be applied to some word lines.

To select a cell string including the target memory cell, a specific voltage may be applied to the string selection line SSL from the recovery interval to the program execution interval.

A recovery voltage (e.g., a ground voltage) may be applied to the first unselected word line WL_unsel1 from the first time point t1 to the second time point t2, and the pass voltage may be applied to the first unselected word line WL_unsel1 from the second time point t2 to the program execution interval.

As in the above description of the first unselected word line WL_unsel1, the recovery voltage may be applied to the second unselected word line WL_unsel2 from the first time point t1 to the second time point t2, and the pass voltage may be applied to the second unselected word line WL_unsel2 from the second time point t2 to the program execution interval.

The precharge voltage may be applied to the selected word line WL_sel from the second time point t2, and the program voltage may be applied to the selected word line WL_sel from the fourth time point t4. In some implementations, the precharge voltage may have a preset voltage level higher than that of the pass voltage and lower than that of the program voltage.

A positive voltage may be applied to the ground selection line GSL from the first time point t1 to the second time point t2 such that the ground selection transistor is turned on; then, the ground voltage may be applied to the ground selection line GSL from the second time point t2 to the third time point t3 such that the ground selection transistor is turned off; then, a positive voltage may be again applied to the ground selection line GSL from the third time point t3.

The second dummy word line DWL2 may be a dummy word line close to the first stack ST1 of FIG. 9.

In some implementations, under control of the control logic 121, a voltage higher than the pass voltage may be applied to the second dummy word line DWL2 from a second dummy control time point dt2 between the first time point t1 and the fourth time point t4.

For example, when the second dummy control time point dt2 follows the second time point t2, the precharge voltage may be applied to the second dummy word line DWL2 after the second time point t2 and before the second dummy control time point dt2.

The first dummy word line DWL1 may be a dummy word distant from the first stack ST1 of FIG. 9.

In some implementations, under control of the control logic 121, a voltage lower than the pass voltage may be applied to the first dummy word line DWL1 from a first dummy control time point dt1 between the first time point t1 and the fourth time point t4.

An example in which the first dummy control time point dt1 is earlier than the second dummy control time point dt2 is illustrated, but the scope of the present disclosure is not limited thereto. The second dummy control time point dt2 may be earlier than the first dummy control time point dt1, or the first dummy control time point dt1 may be the same as the second dummy control time point dt2.

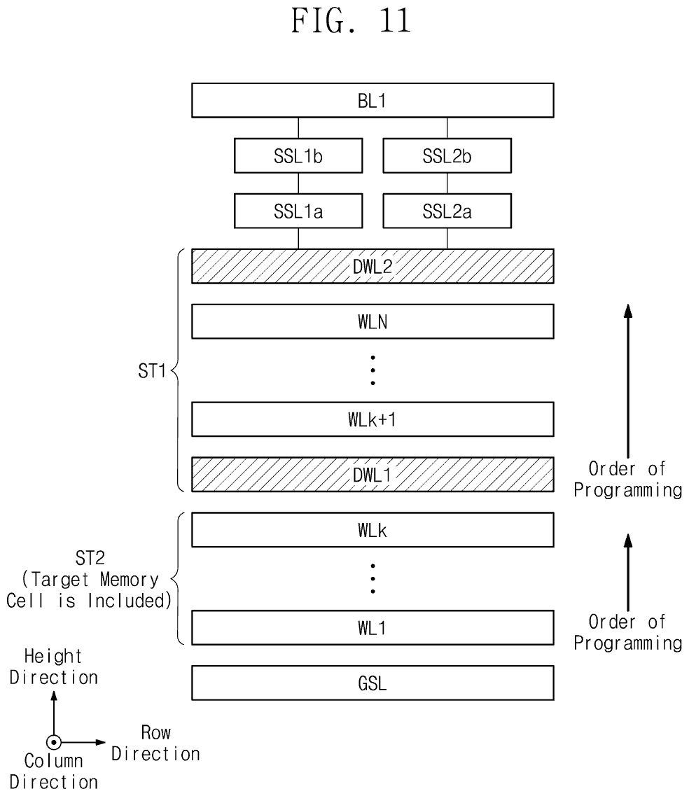

FIG. 11 is a cross-sectional view of a memory block divided into two stacks, according to some implementations of the present disclosure. Referring to FIG. 11, under the assumption that a memory block includes two stacks and is programmed in the B2T manner, as a second example, some operations of independently controlling dummy word lines of the upper stack (e.g., the first stack ST1) when a target memory cell of the lower stack (e.g., the second stack ST2) is programmed in a state where the upper stack is already programmed will be described.

Below, for brevity of description, the description given with reference to FIG. 9 will be omitted to avoid redundancy.

The first stack ST1 may include the first dummy word line DWL1 and the second dummy word line DWL2. The first dummy word line DWL1 may be disposed between the (k+1)-th word line WLk+1 and the second stack ST2. The second dummy word line DWL2 may be disposed between the string selection lines SSL1a, SSL1b, SSL2a, and SSL2b and the N-th word line WLN. The second stack ST2 may include a target memory cell.

The first stack ST1 and the second stack ST2 may be programmed in the B2T manner independently of each other. Accordingly, when a memory cell in the second stack ST2 is programmed, at least one memory cell in the first stack ST1 is already programmed.

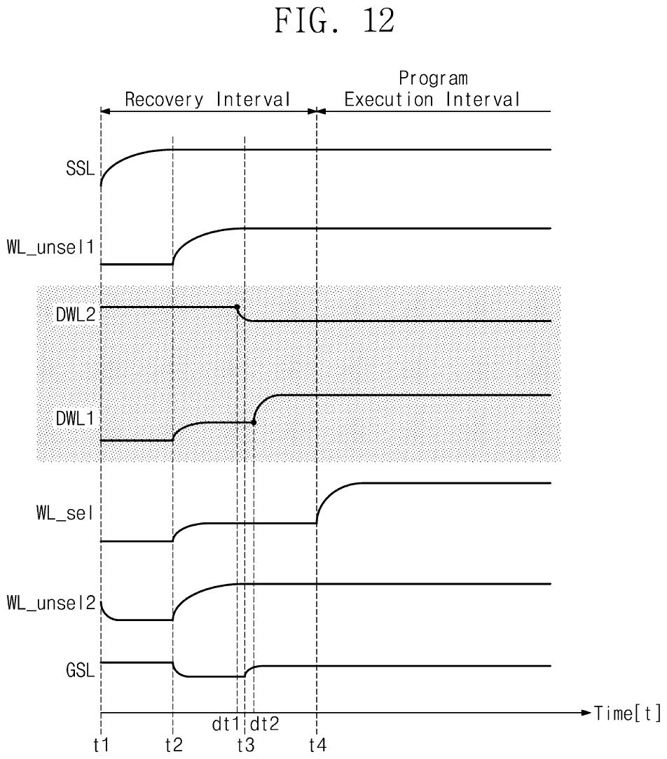

FIG. 12 is a timing diagram describing voltages applied to a memory block of FIG. 9, according to some implementations of the present disclosure. Voltages which are applied to the memory block when the program operation on the target memory cell in the second stack ST2 of FIG. 10 is programmed in a state where the first stack ST1 is programmed will be described with reference to FIG. 12.

A plurality of time points t1 to t4 and each interval are the same as those described with reference to FIG. 10. Also, voltages which are applied to the string selection line SSL, the first and second unselected word lines WL_unsel1 and WL_unsel2, the selected word line WL_sel, and the ground selection line GSL are the same as those described with reference to FIG. 10.

However, in this example, the first dummy word line DWL1 indicates a dummy word line close to the second stack ST2, and the second dummy word line DWL2 indicates a dummy word line distant from the second stack ST2.

The recovery voltage may be applied to the first dummy word line DWL1 from the first time point t1, and then, the voltage higher than the pass voltage may be applied to the first dummy word line DWL1 from the second dummy control time point dt2 to the program execution interval.

In some implementations, when the second dummy control time point dt2 follows the second time point t2, under control of the control logic 121, the precharge voltage is applied to the first dummy word line DWL1 from the second time point t2 to the second dummy control time point dt2.

The recovery voltage may be applied to the second dummy word line DWL2 from the first time point t1, and then, the voltage lower than the pass voltage may be applied to the second dummy word line DWL2 from the first dummy control time point dt1 to the program execution interval.

In some implementations, the voltage lower than the pass voltage applied to the second dummy word line DWL2 is the same as the ground voltage.

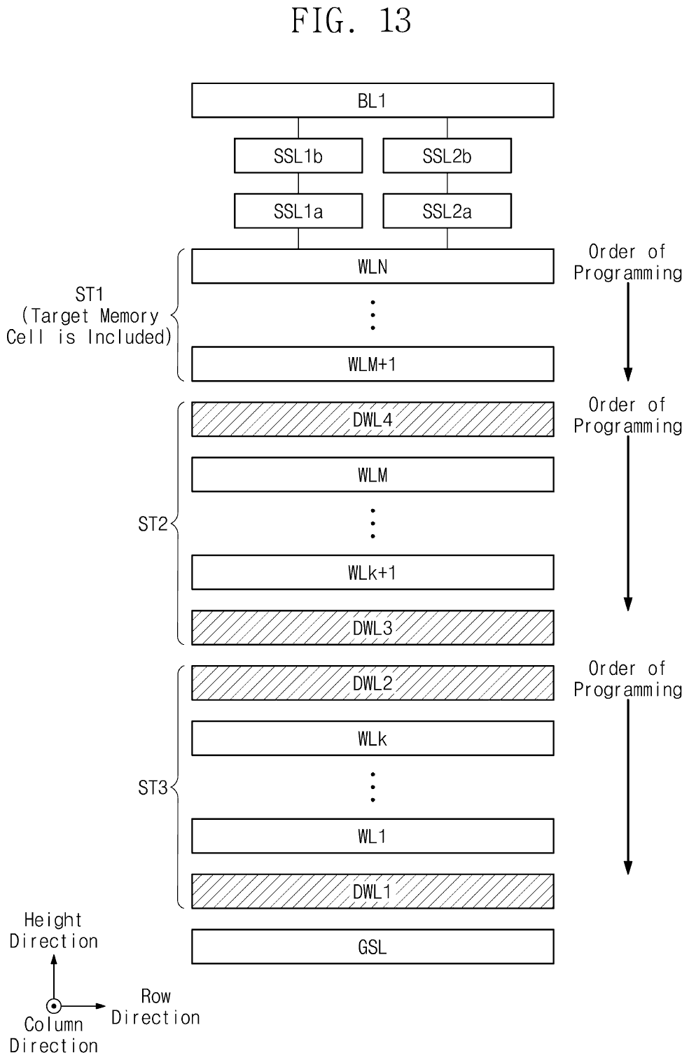

FIG. 13 is a cross-sectional view of a memory block divided into three stacks, according to some implementations of the present disclosure. Referring to FIG. 13, as a third example, a memory block may include three stacks, and when the program operation is performed in the T2B manner, the memory block may include a first stack ST1, a second stack ST2, and a third stack ST3 from the top of the height direction. When a target memory cell of the first stack ST1 is programmed in a state where at least one of the second stack ST2 and the third stack ST3 is already programmed, dummy word lines of the second stack ST2 and the third stack ST3 may be individually controlled.

The first bit line BL1, the string selection lines SSL1a, SSL1b, SSL2a, and SSL2b, and the ground selection line GSL may respectively correspond to the first bit line BL1, the string selection lines SSL1a, SSL1b, SSL2a, and SSL2b, and the ground selection line GSL of FIG. 9.

The third stack ST3 may include the first to k-th word lines WL1 to WLk from the bottom of the height direction. The third stack ST3 may include the first dummy word line DWL1 and the second dummy word line DWL2. The first dummy word line DWL1 may be disposed between the ground selection line GSL and the first word line WL1. The second dummy word line DWL2 may be disposed between the k-th word line WLk and the second stack ST2.

The second stack ST2 may include (k+1)-th to M-th word lines WLk+1 to WLM disposed from the bottom of the height direction. The second stack ST2 may include the third dummy word line DWL3 and the fourth dummy word line DWL4. The third dummy word line DWL3 may be disposed between the third stack ST3 and the (k+1)-th word line WLk+1. The fourth dummy word line DWL4 may be disposed between the M-th word line WLM and the first stack ST1. In some implementations, “M” may be a natural number greater than “k” and smaller than “N”.

The first stack ST1 may include (M+1)-th to N-th word lines WLM+1 to WLN disposed from the bottom of the height direction. The first stack ST1 may include a target memory cell.

Each of the first to third stacks ST1 to ST3 may be individually programmed in the T2B manner. Accordingly, when a target memory cell in the first stack ST1 is programmed, at least one of memory cells in the second stack ST2 or the third stack ST3 is already programmed.

In this case, from a first time point after the verification interval and before program execution interval to a second time point in the program execution interval, under control of the control logic 121, the voltage higher than the pass voltage may be applied to the fourth dummy word line DWL4 the closest to the first stack ST1 from among the first to fourth dummy word lines DWL1 to DWL4.

In some implementations, the first time point corresponds to the second dummy control time point dt2 of FIG. 10.

In some implementations, the voltage higher than the pass voltage is a voltage higher than the first threshold voltage for turning on a transistor of a dummy memory cell connected to the fourth dummy word line DWL4.

Also, from a third time point after the verification interval and before the program execution interval to a fourth time point in the program execution interval, under control of the control logic 121, the voltage lower than the pass voltage may be applied to the first dummy word line DWL1 the most distant from the first stack ST1 from among the first to fourth dummy word lines DWL1 to DWL4.

In some implementations, the third time point corresponds to the first dummy control time point dt1 of FIG. 10.

In some implementations, the voltage lower than the pass voltage is a voltage lower than or equal to the second threshold voltage for turning off a transistor of a dummy memory cell connected to the first dummy word line DWL1.

In some implementations, the voltage lower than the pass voltage is the ground voltage.

In addition, the second dummy word line DWL2 and the third dummy word line DWL3 may be controlled to be similar to an unselected word line.

In some implementations, a dummy word line manager determines whether at least one of the second stack ST2 and the third stack ST3 is programmed, by referring to a program table.

As illustrated in FIG. 13, in some implementations in which the memory block is divided into three stacks ST1 to ST3, when the second stack ST2 includes a target memory cell, a way to control the first dummy word line DWL1 and the second dummy word line DWL2 may be determined depending on whether the third stack ST3 is programmed. In this case, the determination method and the control method may be similar to that described for the case in which a memory block is divided into two stacks as illustrated in FIG. 9.

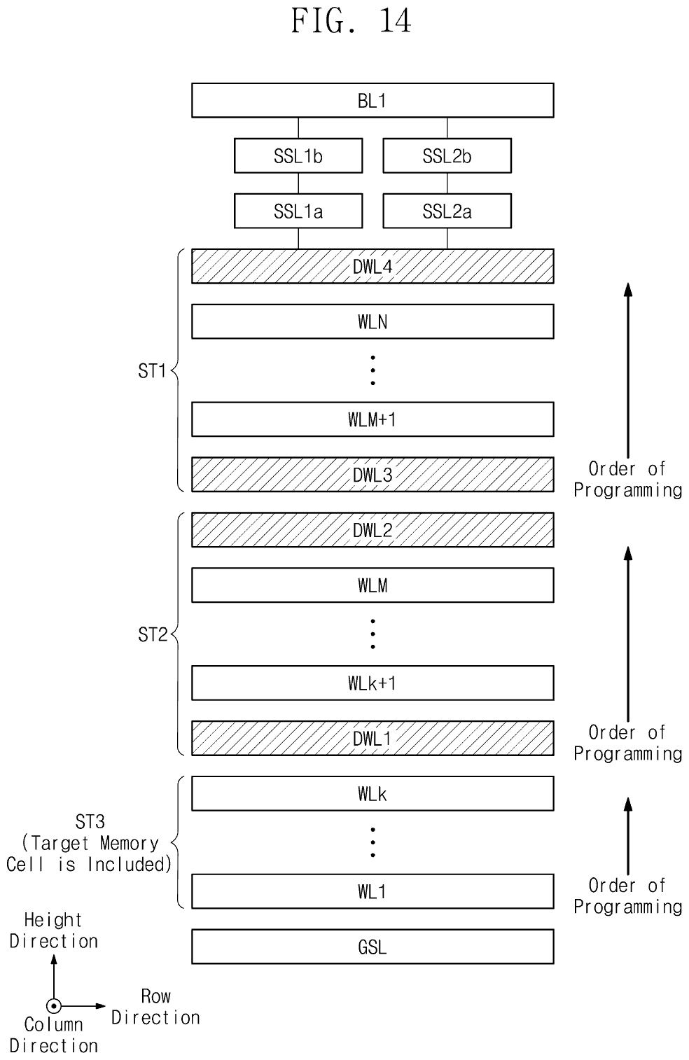

FIG. 14 is a cross-sectional view of a memory block divided into three stacks, according to some implementations of the present disclosure. Referring to FIG. 14, as a fourth example, a memory block may include three stacks, and when the program operation is performed in the B2T manner, the memory block may include a first stack ST1, a second stack ST2, and a third stack ST3 from the top of the height direction. When a target memory cell of the third stack ST3 is programmed in a state where at least one of the first stack ST1 and the second stack ST2 is already programmed, dummy word lines of the first stack ST1 and the second stack ST2 may be individually controlled.

Below, for brevity of description, the description given with reference to FIG. 13 will be omitted to avoid redundancy.

The third stack ST3 may include the first to k-th word lines WL1 to WLk from the bottom of the height direction.

The second stack ST2 may include the first dummy word line DWL1 and the second dummy word line DWL2. The first dummy word line DWL1 may be disposed between the third stack ST3 and the (k+1)-th word line WLk+1. The second dummy word line DWL2 may be disposed between the M-th word line WLM and the first stack ST1.

The first stack ST1 may include the third dummy word line DWL3 and the fourth dummy word line DWL4. The third dummy word line DWL3 may be disposed between the second stack ST2 and the (M+1)-th word line WLM+1. The fourth dummy word line DWL4 may be disposed between the string selection lines SSL1a, SSL1b, SSL2a, and SSL2b and the N-th word line WLN.

Each of the first to third stacks ST1 to ST3 may be individually programmed in the B2T manner. Accordingly, when a target memory cell in the third stack ST3 is programmed, at least one of memory cells in the first stack ST1 or the second stack ST2 is already programmed.

In this case, from a first time point after the verification interval and before program execution interval to a second time point in the program execution interval, under control of the control logic 121, the voltage higher than the pass voltage may be applied to the first dummy word line DWL1 the closest to the third stack ST3 from among the first to fourth dummy word lines DWL1 to DWL4.

In some implementations, the first time point corresponds to the second dummy control time point dt2 of FIG. 12.

In some implementations, the voltage higher than the pass voltage is a voltage higher than the first threshold voltage for turning on a transistor of a dummy memory cell connected to the first dummy word line DWL1.

Also, from a third time point after the verification interval and before program execution interval to a fourth time point in the program execution interval, under control of the control logic 121, the voltage lower than the pass voltage may be applied to the fourth dummy word line DWL4 the most distant from the third stack ST3 from among the first to fourth dummy word lines DWL1 to DWL4.

In some implementations, the third time point corresponds to the first dummy control time point dt1 of FIG. 12.

In some implementations, the voltage lower than the pass voltage is a voltage lower than or equal to the second threshold voltage for turning off a transistor of a dummy memory cell connected to the fourth dummy word line DWL4.

In some implementations, the voltage lower than the pass voltage is the ground voltage.

In some implementations, a dummy word line manager determines whether to at least one of the first stack ST1 and the second stack ST2 is programmed, by referring to a program table.

As illustrated in FIG. 14, in some implementations in which the memory block is divided into three stacks ST1 to ST3, when the second stack ST2 includes a target memory cell, a voltage to be applied to the third dummy word line DWL3 and the fourth dummy word line DWL4 may be determined depending on whether the first stack ST1 is programmed. In this case, the determination method and the control method may be similar to those described for the case in which a memory block is divided into two stacks as illustrated in FIG. 11.

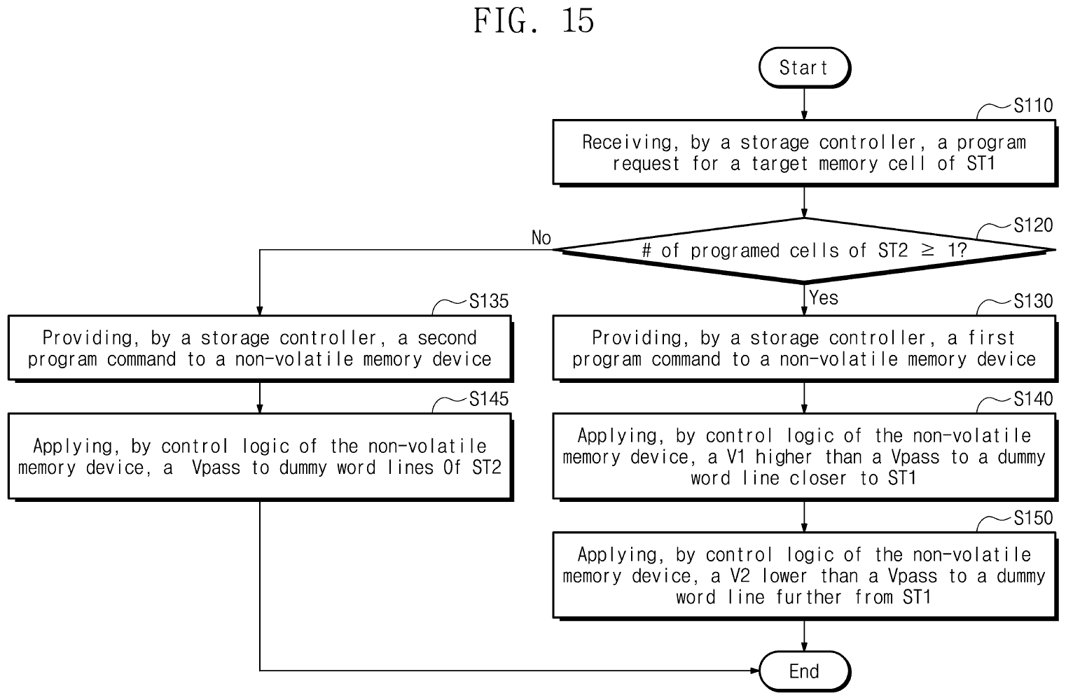

FIG. 15 is a flowchart describing an example of an operating method of a storage device according to some implementations of the present disclosure. The operating method of the storage device of FIG. 1 is illustrated in FIG. 15. The storage device may include a storage controller and a non-volatile memory device.

In operation S110, the storage controller receives the program request for a target memory cell of the first stack ST1 from a host.

In operation S120, the storage controller determines whether the number of programmed memory cells of the second stack ST2 is one or more. When the number of programmed memory cells of the second stack ST2 is one or more, the storage device performs operation S130; a programmed memory cell is absent from the second stack ST2, the storage device may perform operation S135.

In some implementations, the storage controller determines whether the number of programmed memory cells of the second stack ST2 is one or more, by referring to a program table. The program table may include information about a plurality of stacks and program status information corresponding to each of the plurality of stacks.

In operation S130, the storage controller provides a first program command to the non-volatile memory device. The first program command may be or include the individual control program command. In other words, when there is a need to reinforce the channel voltage boosting of an inhibit cell, the storage controller may provide the first program command to the non-volatile memory device.

In operation S140, control logic of the non-volatile memory device applies a first voltage higher than the pass voltage to the first dummy word line closer to the first stack ST1 from among dummy word lines of the second stack ST2, from a first time point after the verification interval and before the program execution interval to a second time point in the program execution interval.

In some implementations, the first voltage is a voltage higher than the first threshold voltage for turning on a dummy memory cell connected to the first dummy word line.

In operation S150, the control logic of the non-volatile memory device applies a second voltage lower than the pass voltage to the second dummy word line distant from the first stack ST1 from among the dummy word lines of the second stack ST2, from a third time point after the verification interval and before the program execution interval to a fourth time point in the program execution interval.

In some implementations, the second voltage is a voltage lower than or equal to the second threshold voltage for turning off a dummy memory cell connected to the second dummy word line.

For convenience of description, an example in which operation S150 is performed after operation S140 is illustrated, but the scope of the present disclosure is not limited thereto. The order of performing operation S140 and operation S150 may be changed; alternatively, depending on the first to fourth time points, operation S140 and operation S150 may partially overlap each other or may be simultaneously performed.

In operation S135, the storage controller provides a second program command to the non-volatile memory device. The second program command may be or include the identical control program command. That is, when it is determined that there is no need to reinforce the channel voltage boosting of an inhibit cell, the storage controller may provide the second program command to the non-volatile memory device.

In operation S145, the control logic of the non-volatile memory device applies the pass voltage to the first dummy word line and the second dummy word line of the second stack ST2 during the program execution interval. That is, the dummy word lines of the second stack ST2 may be controlled to be identical to an unselected word line.

According to some implementations of the present disclosure, a storage device including dummy word lines and an operating method thereof are provided. In a storage device including a plurality of stacks, channel voltage boosting of an unselected memory cell may be reinforced by individually controlling dummy word lines depending on whether stacks are programmed. Accordingly, the disturbance which the unselected memory cell experiences may be alleviated.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to examples thereof, it will be apparent to those of ordinary skill in the art that various changes and modifications may be made thereto without departing from the spirit and scope of the present disclosure.

What is claimed is:

1. A storage device comprising:
a non-volatile memory device including at least one memory block divided into a plurality of stacks arranged in sequence in a vertical direction; and
a storage controller,
wherein the storage controller is configured to, based on a program request for a target memory cell of a first stack among the plurality of stacks:
determine that a number of programmed memory cells of a second stack among the plurality of stacks is one or more, and
based on determining that the number of the programmed memory cells of the second stack is one or more, provide a first program command to the non-volatile memory device,
wherein the second stack includes a first dummy word line and a second dummy word line arranged adjacent to an upper end and a lower end of the second stack, respectively, and
wherein control logic of the non-volatile memory device is configured to, based on the first program command:
apply a first voltage, greater than a pass voltage applied to an unselected word line of the non-volatile memory device, to a dummy word line closer to the first stack from among the first and second dummy word lines, and
apply a second voltage, smaller than the pass voltage, to a dummy word line more distant from the first stack from among the first and second dummy word lines.

2. The storage device of claim 1, wherein the control logic of the non-volatile memory device is configured to:
apply the first voltage to the dummy word line closer to the first stack from (i) a first time point after a verification interval and before a program execution interval to (ii) a second time point in the program execution interval; and
apply the second voltage to the dummy word line more distant from the first stack from (i) a third time point after the verification interval and before the program execution interval to (ii) a fourth time point in the program execution interval.

3. The storage device of claim 2, wherein each of the first time point and the second time point is after an initial word line setting interval and before the program execution interval.

4. The storage device of claim 1, wherein the storage controller is configured to, based on a second program request, provide a second program command to the non-volatile memory device in response to determining that a programmed memory cell is absent from the second stack, and
wherein the control logic of the non-volatile memory device is configured to, based on the second program command, apply the pass voltage to each of the first and second dummy word lines, during a program execution interval.

5. The storage device of claim 1, wherein the non-volatile memory device is configured to program the at least one memory block in a top-to-bottom (T2B) manner,
wherein the first stack is disposed above the second stack in the vertical direction, and
wherein the control logic of the non-volatile memory device is configured to apply the first voltage to the first dummy word line and to apply the second voltage to the second dummy word line.

6. The storage device of claim 1, wherein the non-volatile memory device is configured to program the at least one memory block in a bottom-to-top (B2T) manner,
wherein the second stack is disposed above the first stack in the vertical direction, and
wherein the control logic of the non-volatile memory device is configured to apply the first voltage to the second dummy word line and to apply the second voltage to the first dummy word line.

7. The storage device of claim 1, wherein the first voltage is greater than a threshold voltage for turning on a dummy memory cell connected to the dummy word line closer to the first stack.

8. The storage device of claim 1, wherein the second voltage is smaller than or equal to a threshold voltage for turning off a dummy memory cell connected to the dummy word line more distant from the first stack.

9. The storage device of claim 1, wherein the target memory cell is connected to a selected word line and a first selected string, and
wherein the control logic of the non-volatile memory device is configured to:
boost a channel voltage of an inhibit cell connected to the selected word line and a second selected string, by applying the first voltage to the dummy word line closer to the first stack during a program execution interval for programming the target memory cell; and
reduce leakage in the vertical direction through the first selected string, by applying the second voltage to the dummy word line more distant from the first stack during the program execution interval.

10. The storage device of claim 1, wherein the storage controller includes:
a program table configured to store program status information corresponding to the first stack and the second stack;
a dummy word line manager configured to determine whether the number of the programmed memory cells of the second stack is one or more, by referring to the program table; and
a command manager configured to generate the first program command and to provide the first program command to the non-volatile memory device, based on determining that the number of the programmed memory cells of the second stack is one or more.

11. A storage device comprising:
a non-volatile memory device including at least one memory block divided into a plurality of stacks arranged in sequence in a vertical direction; and
a storage controller,
wherein the storage controller is configured to, based on a program request for a target memory cell of a first stack among the plurality of stacks:
determine that a combined number of programmed memory cells of a second stack and a third stack among the plurality of stacks is one or more, and
based on determining that the combined number of the programmed memory cells is one or more, provide a first program command to the non-volatile memory device,
wherein the second stack includes a first dummy word line and a second dummy word line disposed adjacent to an upper end and a lower end of the second stack, respectively,
wherein the third stack includes a third dummy word line and a fourth dummy word line disposed adjacent to an upper end and a lower end of the third stack, respectively, and
wherein control logic of the non-volatile memory device is configured to, based on the first program command:
apply a first voltage, greater than a pass voltage applied to an unselected word line of the non-volatile memory device, to a dummy word line closest to the first stack from among the first to fourth dummy word lines, and
apply a second voltage, smaller than the pass voltage, to a dummy word line most distant from the first stack from among the first to fourth dummy word lines.

12. The storage device of claim 11, wherein the control logic of the non-volatile memory device is configured to:
apply the first voltage to the dummy word line closest to the first stack from (i) a first time point after a verification interval and before a program execution interval to (ii) a second time point in the program execution interval; and
apply the second voltage to the dummy word line most distant from the first stack from (i) a third time point after the verification interval and before the program execution interval to (ii) a fourth time point in the program execution interval.

13. The storage device of claim 11, wherein the non-volatile memory device is configured to program the at least one memory block in a top-to-bottom (T2B) manner,
wherein the first stack is disposed above the second stack in the vertical direction,
wherein the second stack is disposed above the third stack in the vertical direction, and
wherein the control logic of the non-volatile memory device is configured to apply the first voltage to the first dummy word line and to apply the second voltage to the fourth dummy word line.

14. The storage device of claim 13, wherein the control logic of the non-volatile memory device is configured to apply the pass voltage to the second and third dummy word lines.

15. The storage device of claim 11, wherein the non-volatile memory device is configured to program the at least one memory block in a bottom-to-top (B2T) manner,
wherein the second stack is disposed above the third stack in the vertical direction,
wherein the third stack is disposed above the second stack in the vertical direction, and
wherein the control logic of the non-volatile memory device is configured to apply the first voltage to the second dummy word line and to apply the second voltage to the third dummy word line.

16. The storage device of claim 15, wherein the control logic of the non-volatile memory device is configured to apply the pass voltage to the first and fourth dummy word lines.

17. The storage device of claim 11, wherein the first voltage is greater than a threshold voltage for turning on a dummy memory cell connected to the dummy word line closest to the first stack.

18. The storage device of claim 11, wherein the second voltage is smaller than or equal to a threshold voltage for turning off a dummy memory cell connected to the dummy word line most distant from the first stack.

19. An operating method of a storage device, wherein the storage device includes (i) a non-volatile memory device including at least one memory block divided into a plurality of stacks arranged in sequence in a vertical direction and (ii) a storage controller, the method comprising:
determining, by the storage controller, whether a number of programmed memory cells of a second stack among the plurality of stacks is one or more, based on a program request for a target memory cell of a first stack among the plurality of stacks,
wherein the second stack includes a first dummy word line and a second dummy word line disposed adjacent to an upper end and a lower end of the second stack, respectively;
providing, by the storage controller, a first program command to the non-volatile memory device, in response to determining that the number of the programmed memory cells is one or more;
applying, by control logic of the non-volatile memory device, a first voltage higher than a pass voltage to a dummy word line closer to the first stack from among the first and second dummy word lines, based on the first program command, wherein the pass voltage is a voltage applied to an unselected word line of the non-volatile memory device; and
applying, by the control logic of the non-volatile memory device, a second voltage lower than the pass voltage to a dummy word line more distant from the first stack from among the first and second dummy word lines, based on the first program command.

20. The method of claim 19, wherein the storage controller includes a program table,
wherein the program table is configured to store program status information corresponding to the first stack and the second stack, and
wherein determining whether the number of the programmed memory cells of the second stack is one or more comprises:
obtaining, by the storage controller, program status information corresponding to the second stack, by referring to the program table; and
determining whether the program status information corresponding to the second stack indicates whether the number of the programmed memory cells of the second stack is one or more.
